(19) United States
(12) Patent Application Publication
(10) Pub. No.: US 2019/0189470 A1
(43) Pub. Date: Jun. 20, 2019

(54) WAFER CLEANING APPARATUS

(71) Applicant: SAMSUNG ELECTRONICS CO., LTD., Suwon-si (KR)

(72) Inventors: Jong Myung PARK, Seoul (KR); Dong Woo LEE, Hwaseong-si (KR); Jin Hong LEE, Hwaseong-si (KR); Young Seok JUNG, Suwon-si (KR); Kang Min PAEK, Hwaseong-si (KR)

(21) Appl. No.: 16/039,384

(22) Filed: Jul. 19, 2018

(30) Foreign Application Priority Data
Dec. 20, 2017 (KR) 10-2017-0175715

(51) Int. Cl. H01L 21/67; H01L 21/687; H01L 21/02; B08B 1/00; B08B 1/04; B08B 3/02

(52) U.S. Cl. CPC H01L 21/67046; H01L 21/68764; H01L 21/67051; B08B 3/022; B08B 1/002; B08B 1/04; H01L 21/02057

(57) ABSTRACT

A wafer cleaning apparatus includes a wafer roller to rotate a wafer in a first direction, first and second roller brushes disposed to be parallel to each other, the first and second roller brushes to be brought into contact with opposing surfaces of the wafer to clean the opposing surfaces of the wafer, respectively, while rotating in mutually opposing directions, first and second pipes having a longitudinal direction parallel to each other, the first and second pipes being above the first and second roller brushes and conveying a cleaning liquid for cleaning the wafer, first and second nozzle groups disposed along the longitudinal direction of the pipes, respectively, and including a plurality of nozzles to spray the cleaning liquid onto the opposing surfaces of the wafer at a predetermined angle, respectively, and a binding part connecting the first and second pipes to restrain movement of the first and second pipes.

### CROSS-REFERENCE TO RELATED APPLICATION

Korean Patent Application No. 10-2017-0175715, filed on Dec. 20, 2017, in the Korean Intellectual Property Office, and entitled: “Wafer Cleaning Apparatus,” is incorporated by reference herein in its entirety.

### BACKGROUND

### 1. Field

Embodiments relate to a wafer cleaning apparatus.

### 2. Description of the Related Art

As the development of integration techniques in the semiconductor industry has accelerated, various films formed on a wafer tend to have a high step portion, which may pose a challenge to providing stable processing and yield. Accordingly, planarization technologies have come to prominence, and among them, a chemical mechanical polishing (CMP) technology has been widely employed. A degree of polishing may affect semiconductor yield and quality.

### SUMMARY

Embodiments are directed to a wafer cleaning apparatus, including a wafer roller to rotate a wafer in a first direction, first and second roller brushes disposed to be parallel to each other, the first and second roller brushes to be brought into contact with opposing surfaces of the wafer to clean the opposing surfaces of the wafer, respectively, while rotating in mutually opposing directions, first and second pipes having a longitudinal direction parallel to each other, the first and second pipes being above the first and second roller brushes and conveying a cleaning liquid for cleaning the wafer, first and second nozzle groups disposed along the longitudinal direction of the first and second pipes, respectively, and including a plurality of nozzles to spray the cleaning liquid onto the opposing surfaces of the wafer at a predetermined angle, respectively, and a binding part connecting the first and second pipes to restrain movement of the first and second pipes.

Embodiments are also directed to a wafer cleaning apparatus, including first and second roller brushes disposed to be adjacent and parallel to each other in a longitudinal direction, to clean a front surface and a rear surface of a wafer, respectively, and to rotate in mutually opposing directions, first and second pipes disposed to be parallel to each other above the first and second roller brushes, and allowing a cleaning liquid for cleaning the wafer to be introduced into the first and second pipes, first and second nozzle groups disposed along the longitudinal direction of the first and second pipes, respectively, and including a plurality of nozzles to spray the cleaning liquid to the front surface and the rear surface of the wafer at a predetermined angle, respectively, and a binding part connecting the first and second pipes to restrain movement of the first and second pipes.

Embodiments are also directed to a wafer cleaning apparatus, including first and second pipes disposed to be parallel to each other to face a front surface and a rear surface, respectively, of a vertically oriented wafer, the first and second pipes each including a plurality of nozzles to spray a cleaning liquid, a number of nozzles of the first pipe being greater than a number nozzles of the second pipe, a binding part connecting and fixing the first and second pipes, and first and second roller brushes disposed to be parallel to each other, the first and second roller brushes to be brought into contact with the front surface and the rear surface of the wafer to clean the front surface and the rear surface, respectively, while rotating in mutually opposing directions.

### BRIEF DESCRIPTION OF THE DRAWINGS

Features will become apparent to those of skill in the art by describing in detail example embodiments with reference to the attached drawings in which:

FIG. 1 illustrates a plan view schematically illustrating a chemical mechanical polishing (CMP) facility employing a wafer cleaning apparatus according to an example embodiment;

FIG. 2 illustrates a plan view of a wafer cleaning apparatus according to an example embodiment;

FIG. 3 illustrates a side view of the wafer cleaning apparatus of FIG. 2 in a direction of I;

FIG. 4 illustrates a side view of the wafer cleaning apparatus of FIG. 2 in a direction of II;

FIG. 5A illustrates a graph illustrating a cleaning effect of a wafer cleaning apparatus according to a comparative example; and

FIG. 5B illustrates a graph illustrating a cleaning effect of a wafer cleaning apparatus according to an example embodiment.

### DETAILED DESCRIPTION

Example embodiments will now be described in detail with reference to the accompanying drawings.

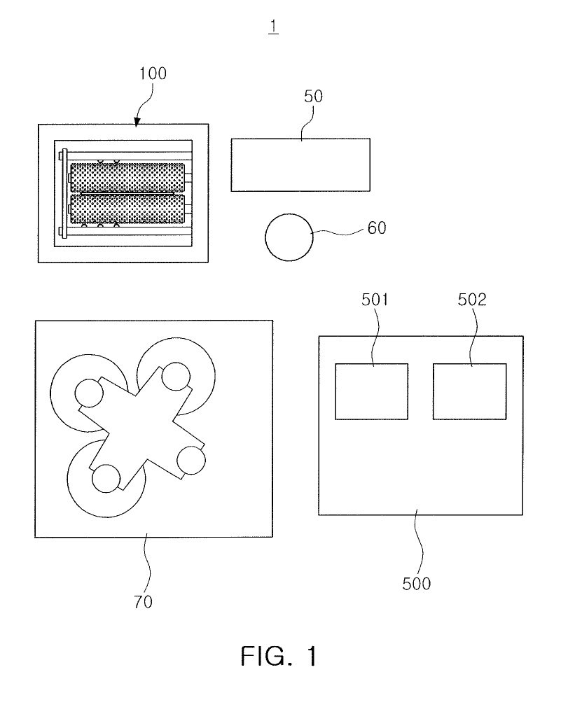

First, a chemical mechanical polishing (CMP) facility will be described with reference to FIG. 1. FIG. 1 is a plan view schematically illustrating a CMP facility employing a wafer cleaning apparatus according to an example embodiment.

The CMP facility 1 may include a load lock facility 50 in which a cassette on which a plurality of wafers are stacked is placed, a polishing apparatus 70 performing a planarization process on a wafer, a wafer transfer robot 60 loading or unloading a wafer to or from the polishing apparatus 70, a wafer cleaning apparatus 100 performing a cleaning process on a wafer unloaded from the polishing apparatus 70, and a pre-inspection apparatus 500. The pre-inspection apparatus 500 may include a load cup part 501 for mounting a load cup facility and a head part 502 for mounting a polishing head.

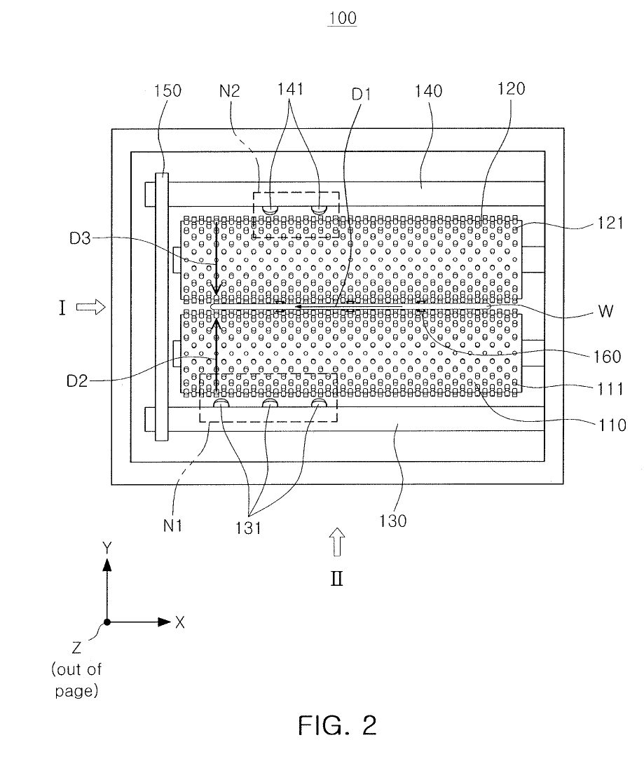

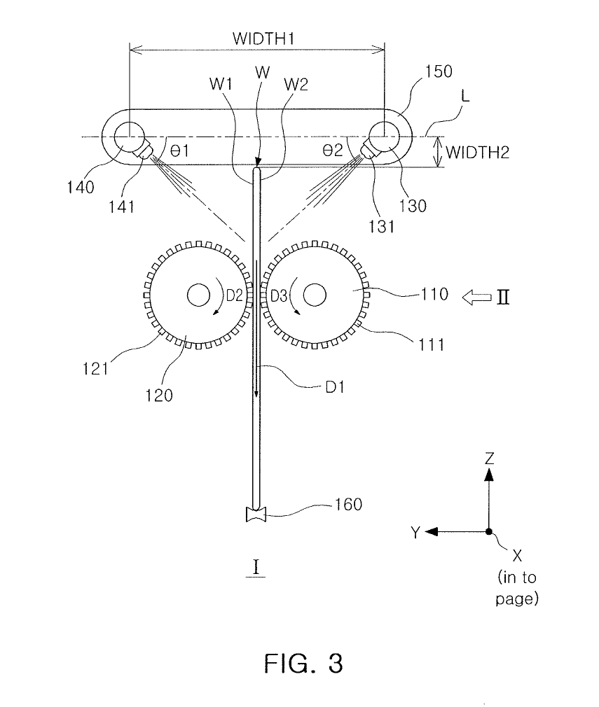

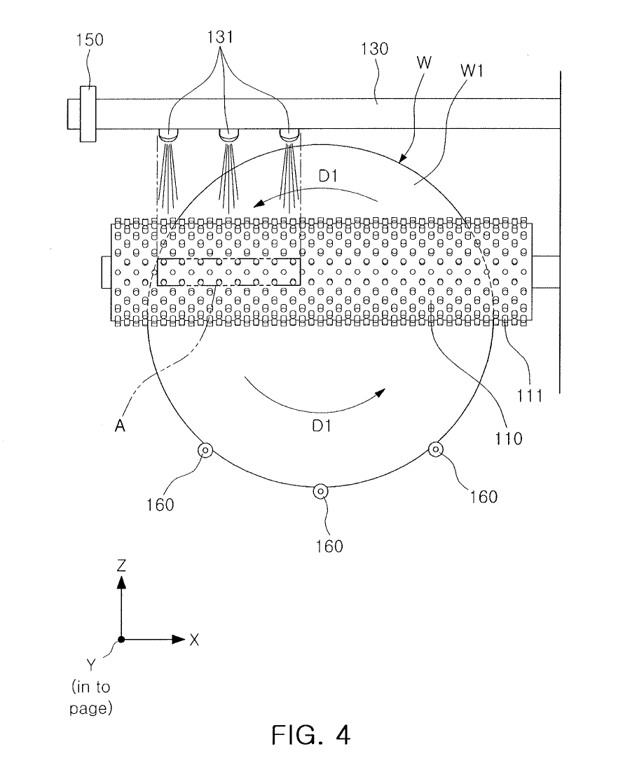

Hereinafter, the wafer cleaning apparatus 100 will be described with reference to FIG. 2 through FIG. 4. FIG. 2 is a plan view (from above) of a wafer cleaning apparatus according to an example embodiment, FIG. 3 is a side view of the wafer cleaning apparatus of FIG. 2 viewed in a direction I in FIG. 2, and FIG. 4 is a side view of the wafer cleaning apparatus of FIG. 2 viewed in a direction II in FIGS. 2 and 3.

Referring to FIGS. 2 and 3, the wafer cleaning apparatus 100 according to an example embodiment may include first and second roller brushes 110 and 120, first and second pipes 130 and 140, first and second nozzle groups N1 and N2, and a binding part 150.

The first and second roller brushes 110 and 120 may be arranged to face each other with a wafer W (on which a cleaning operation is to be performed) interposed therebetween. The wafer W may be a semiconductor substrate on which the CMP process has been performed in a previous stage.

The first roller brush 110 may be disposed to be in contact with a front surface W1 of the wafer W and the second roller brush 120 may be disposed to be in contact with a rear surface W2 of the wafer W. The first and second roller brushes 110 and 120 may rotate in different directions D2 and D3 and clean the front surface W1 and the rear surface W2 of the wafer W, respectively. The first and second roller brushes 110 and 120 may have a length (e.g., in a lengthwise direction along the x-axis in FIG. 2) greater than a radius of the wafer W.

Protrusions 111 and 121 for improving a cleaning effect of the wafer W may be provided on the surfaces of the first and second roller brushes 110 and 120, respectively. Also, the front surface W1 of the wafer W may be a surface on which a semiconductor layer for manufacturing a semiconductor chip has been grown.

The wafer W may be rotated in a first direction D1 (for example, counter-clockwise as shown in FIG. 4, or out of the page at the top of the wafer W and into the page at the bottom of the wafer W as shown in FIG. 3) between the first and second roller brushes 110 and 120 by a wafer roller 160. In an example embodiment, for example, three wafer rollers 160 may be disposed (see FIG. 4). According to an example embodiment, a plurality of idlers may support the wafer W and a single wafer roller 160 may rotate the wafer W.

The wafer roller 160 may be rotated by a driving device such as a motor. The wafer roller 160 may be brought into contact with an edge portion of the wafer W, and as the wafer roller 160 rotates, the wafer W may rotate in a first direction D1. For example, referring to FIG. 4, the wafer roller may rotate in a clockwise direction and the wafer W may rotate in a counter-clockwise direction.

The first and second pipes 130 and 140 may have flow channels through which a cleaning liquid to be sprayed to the wafer W is supplied. The first and second pipes 130 and 140 may have a long cylindrical rod shape and may be disposed to be parallel to each other, with the wafer W interposed therebetween, and may be disposed above the first and second roller brushes 110 and 120. The first and second pipes 130 and 140 may have substantially the same length, and first and second nozzle groups N1 and N2 including a plurality of nozzles 131 and 141 may be disposed in the first and second pipes 130 and 140, respectively.

The first and second nozzle groups N1 and N2 may be arranged to face the front surface W1 and the rear surface W2 of the wafer W in a longitudinal length direction of the first and second pipes 130 and 140, respectively. The first and second nozzle groups N1 and N2 may be arranged to spray a cleaning liquid at predetermined angles θ1 and θ2 toward the front surface W1 and the rear surface W2 of the wafer W, respectively.

Referring to FIG. 4, the first and second nozzle groups N1 and N2 may be arranged to spray the cleaning liquid to a region A in which the wafer W rotates between the first and second roller brushes 110 and 120, i.e., to a region in which a rotation direction D1 of the wafer W and rotation directions D2 and D3 of the first and second roller brushes 110 and 120 match. Since the region A is a region in which the wafer W, while being introduced to space between the first and second roller brushes 110 and 120, is cleaned, when the cleaning liquid is sprayed to the region, the cleaning liquid may be sufficiently used during a cleaning process of the first and second roller brushes 110 and 120.

Referring to FIG. 3, the nozzles 131 and 141 of the first and second nozzle groups N1 and N2 may be positioned with a tilt of, for example, 50° to 70° with respect to the front surface W1 and the rear surface W2 of the wafer W to spray the cleaning liquid. For example, angles θ1 and 02 may independently be about 50° to about 70°. The plurality of nozzles 131 and 141 may be arranged in a row at a predetermined interval in the first and second pipes 130 and 140.

The plurality of nozzles 131 and 141 of the first and second nozzle groups N1 and N2 may be arranged such that an injection amount of the cleaning liquid injected per unit time is uniform. In an implementation, the injection amount per unit time may be about 500 ml/min or more to supply a suitable amount of the cleaning liquid required for cleaning the wafer W.

Further, the amount of the plurality of nozzles 131 of the first nozzle group N1 may be greater than the amount of the plurality of nozzles 141 of the second nozzle group N2 so that an injection amount of the cleaning liquid injected from the first nozzle group N1 per unit time is greater than an injection amount of the cleaning liquid injected from the second nozzle group N2 per unit time. In an implementation, the front surface W1 of the wafer W may be a surface on which a semiconductor layer has been grown and the amount of the cleaning liquid sprayed to the front surface W1 of the wafer W may be greater than that of the cleaning liquid sprayed to the rear surface W2 of the wafer W.

The binding part 150 may connect and fix regions of the first and second pipes 130 and 140, whereby spray angles of the plurality of nozzles 131 and 141 of the first and second nozzle groups N1 and N2 may be fixed. The binding part 150 may be prepared separately from the first and second pipes 130 and 140 and adhered or press-fit to the first and second pipes 130 and 140, or may be integrally formed with the first and second tubing tubes 130 and 140. The binding part 150 may be disposed to connect first ends of the first and second pipes 130 and 140. In an implementation, the binding part 150 may be disposed proximate to ends of the first and second pipes 130 and 140 that are opposite to ends where the cleaning liquid is supplied and may space apart centers of the first and second pipes 130 and 140 by a first width WIDTH1 in a y-axis direction. The binding part 150 may fix a centerline L of the first and second pipes 130 and 140 by a second width (distance) WIDTH2 above the wafer W in a z-axis direction. In other implementations, the binding part 150 may be disposed in another region suitable to firmly fix the first and second pipes 130 and 140.

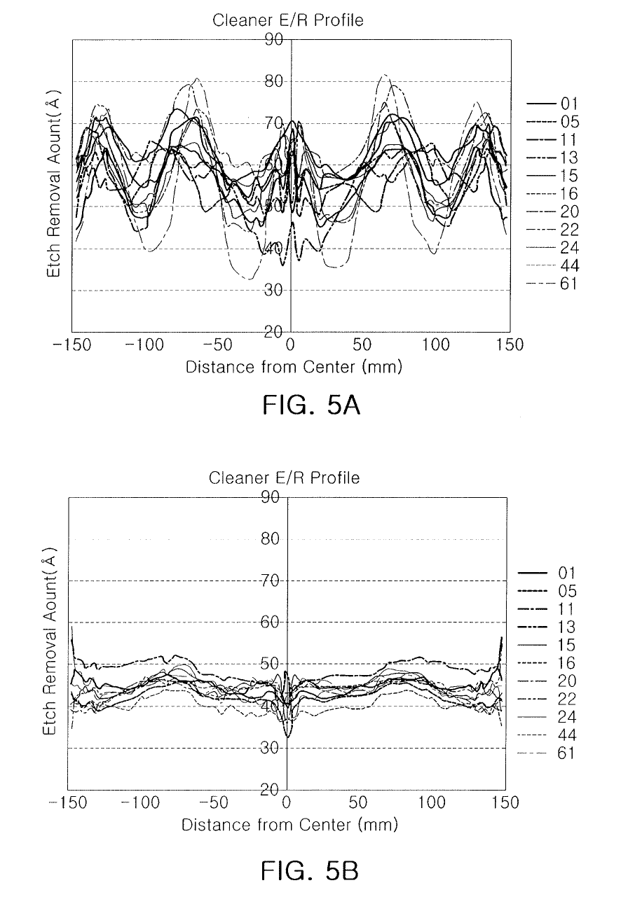

The binding part 150 may connect and fix the first and second pipes 130 and 140. Thus, the first and second pipes 130 and 140 may not rotate with respect to a central portion thereof in a longitudinal direction, preventing a change in the spray angle of the plurality of nozzles 131 and 141 of the first and second nozzle groups N1 and N2. Therefore, the cleaning liquid may be uniformly applied to the wafer W at a predetermined angle. On the other hand, if the first and second pipes are separated, e.g., without the binding part 150, the angle of spraying the cleaning liquid may change due to vibrations generated during a manufacturing process, in which case an area of a surface, for example, the front surface W1, of the wafer W to which a large amount of the cleaning liquid has been sprayed may be excessively cleaned to have a surface profile lower than that intended and an area of the surface of the water to which a small amount of cleaning liquid has been sprayed may have a surface profile higher than intended. If the surface profiles of the wafers differ by regions, quality of semiconductor chips manufactured in the wafer may not be uniform. These effects will be described with reference to FIGS. 5A and 5B.

FIG. 5A is a graph illustrating a cleaning effect of a wafer cleaning apparatus according to a comparative example, and FIG. 5B is a graph illustrating a cleaning effect of a wafer cleaning apparatus according to an example embodiment.

In the comparative example of FIG. 5A in which a binding part is not provided, it can be seen that a surface profile has a height difference of about 50 Å according to regions of the wafer. In contrast, in the case of FIG. 5B, it can be seen that a surface profile has a height difference of about 20 Å or less, which is relatively uniform, compared with the comparative example. Therefore, the wafer cleaning apparatus of an example embodiment may improve efficiency of the CMP process.

By way of summation and review, facilities used in a CMP process may include a polishing apparatus performing polishing and a wafer cleaning apparatus performing cleaning. The wafer cleaning apparatus may be used for removing slurry residues and other particles remaining on a polished wafer.

As set forth above, embodiments may enhance efficiency of equipment used in a chemical mechanical polishing (CMP) process. Embodiments may provide a wafer cleaning apparatus that may increase efficiency of the CMP process.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A wafer cleaning apparatus, comprising:
a wafer roller to rotate a wafer in a first direction;
first and second roller brushes disposed to be parallel to each other, the first and second roller brushes to be brought into contact with opposing surfaces of the wafer to clean the opposing surfaces of the wafer, respectively, while rotating in mutually opposing directions;
first and second pipes having a longitudinal direction parallel to each other, the first and second pipes being above the first and second roller brushes and conveying a cleaning liquid for cleaning the wafer;
first and second nozzle groups disposed along the longitudinal direction of the first and second pipes, respectively, and including a plurality of nozzles to spray the cleaning liquid onto the opposing surfaces of the wafer at a predetermined angle, respectively; and
a binding part connecting the first and second pipes to restrain movement of the first and second pipes.

2. The wafer cleaning apparatus as claimed in claim 1, wherein a total number of the plurality of nozzles constituting the first nozzle group is greater than a total number of the plurality of nozzles constituting the second nozzle group.

3. The wafer cleaning apparatus as claimed in claim 1, wherein the first and second nozzle groups are disposed to spray the cleaning liquid toward a region in which the first direction and a rotation direction of each of the first and second roller brushes match.

4. The wafer cleaning apparatus as claimed in claim 1, wherein the first and second nozzle groups are disposed to spray the cleaning liquid at an angle of 50° to 70° with respect to the opposing surfaces of the wafer.

5. The wafer cleaning apparatus as claimed in claim 1, wherein the first and second nozzle groups are disposed to spray the cleaning liquid at substantially the same angle with respect to each of the opposing surfaces of the wafer.

6. The wafer cleaning apparatus as claimed in claim 1, wherein:
the first and second pipes have substantially the same shape, and
the binding part is connected to regions of the first and second pipes corresponding to each other.

7. The wafer cleaning apparatus as claimed in claim 1, wherein the nozzles constituting the first and second nozzle groups are disposed to spray the cleaning liquid in substantially a same amount per unit time.

8. The wafer cleaning apparatus as claimed in claim 7, wherein the amount of the cleaning liquid per unit time is 500 ml/min. or greater.

9. The wafer cleaning apparatus as claimed in claim 1, wherein the first and second nozzle groups are disposed to slope downwards at the predetermined angle with respect to a central portion of each of the first and second pipes in the longitudinal direction.

10. The wafer cleaning apparatus as claimed in claim 1, wherein the nozzles of the first and second nozzle groups are disposed in respective rows and at a predetermined interval in each row.

11. The wafer cleaning apparatus as claimed in claim 1, wherein the wafer is a semiconductor substrate that has undergone chemical mechanical polishing.

12. The wafer cleaning apparatus as claimed in claim 1, wherein the first and second pipes have substantially a same length.

13. A wafer cleaning apparatus, comprising:
first and second roller brushes disposed to be adjacent and parallel to each other in a longitudinal direction, to clean a front surface and a rear surface of a wafer, respectively, and to rotate in mutually opposing directions;
first and second pipes disposed to be parallel to each other above the first and second roller brushes, and allowing a cleaning liquid for cleaning the wafer to be introduced into the first and second pipes;
first and second nozzle groups disposed along the longitudinal direction of the first and second pipes, respectively, and including a plurality of nozzles to spray the cleaning liquid to the front surface and the rear surface of the wafer at a predetermined angle, respectively; and
a binding part connecting the first and second pipes to restrain movement of the first and second pipes.

14. The wafer cleaning apparatus as claimed in claim 13, wherein the cleaning liquid is introduced into the first and second pipes at substantially a same flow rate.

15. The wafer cleaning apparatus as claimed in claim 14, wherein an amount of the cleaning liquid sprayed from the first nozzle group per unit time is greater than an amount of the cleaning liquid sprayed from the second nozzle group per unit time.

16. The wafer cleaning apparatus as claimed in claim 13, further comprising a wafer roller to rotate the wafer in a first direction.

17. The wafer cleaning apparatus as claimed in claim 16, wherein the first and second nozzle groups are disposed to spray the cleaning liquid toward a region in which the first direction and a rotation direction of each of the first and second roller brushes match.

18. A wafer cleaning apparatus, comprising:
first and second pipes disposed to be parallel to each other to face a front surface and a rear surface, respectively, of a vertically oriented wafer, the first and second pipes each including a plurality of nozzles to spray a cleaning liquid, a total number of nozzles of the first pipe being greater than a total number nozzles of the second pipe;
a binding part connecting and fixing the first and second pipes; and
first and second roller brushes disposed to be parallel to each other, the first and second roller brushes to be brought into contact with the front surface and the rear surface of the wafer to clean the front surface and the rear surface, respectively, while rotating in mutually opposing directions.

19. The wafer cleaning apparatus as claimed in claim 18, wherein the front surface of the wafer is a surface on which a semiconductor layer has been grown.

20. The wafer cleaning apparatus as claimed in claim 18, further comprising a wafer roller to rotate the wafer in a first direction.
